(19) United States
(12) Patent Application Publication
(10) Pub. No.: US 2026/0182413 A1
(43) Pub. Date: Jun. 25, 2026

(54) SELF-ALIGNED CORE PATTERN

(71) Applicant: Intel Corporation, Santa Clara, CA (US)

(72) Inventors: Jeremy Ecton, Gilbert, AZ (US); Srinivas Pietambaram, Chandler, AZ (US); Gang Duan, Chandler, AZ (US); Brandon Marin, Gilbert, AZ (US)

(73) Assignee: Intel Corporation, Santa Clara, CA (US)

(21) Appl. No.: 19/000,239

(22) Filed: Dec. 23, 2024

(51) Int. Cl. H01L 23/498; H01L 21/48; H01L 23/15

(52) U.S. Cl. CPC H10W 70/65; H10W 70/095; H10W 70/635; H10W 70/692

(57) ABSTRACT

An apparatus comprises a glass panel comprising a first surface, a trench in the first surface, and a routing structure over the first surface. A conductive trace comprises a first portion within the trench and a second portion above the first surface. The conductive trace extends laterally a length. The length is greater than a width of the conductive trace. The first portion extends a depth below the first surface, the second portion extends a height above the first surface, and the depth is at least ten percent or at least twenty percent of the height. The second portion comprises a sidewall with a concave or a planar profile. The glass panel comprises a second surface opposite the first surface. A through glass via (TGV) extends between the first and second surfaces. The TGV is coupled with the conductive trace.

### BACKGROUND

In electronics manufacturing, integrated circuit (IC) packaging is a stage of semiconductor device fabrication in which an IC that has been monolithically fabricated on a chip (or die) is assembled into a “package” that can protect the IC chip from physical damage. The package connects the IC chip to other packaged IC chips and/or a scaled host component, such as a package substrate, or a printed circuit board. Multiple IC chips can be assembled into a multi-die package. Some IC packages include interposers, which are substrates used to connect multiple chips or dies within an integrated circuit (IC) package.

Traditionally, package substrates and interposers were made from organic materials. More recently, package substrates and interposers with a glass core between layers of organic materials have been introduced. A substrate with a glass core has advantages over conventional substrates with an organic core including low total thickness variation (TTV), high plated-through-hole (PTH) density, high dimensional stability, and high strength.

The layers of organic materials over the surfaces of a glass-cored package substrate or interposer generally include redistribution structures having one or more redistribution layers (RDL), as well as interconnect features on the top and bottom surfaces of the redistribution structures. Package substrates and interposers with glass cores also generally includes through-glass vias (TGVs). The redistribution structures and the TGVs couple the top and bottom interconnect features so that the package substrate or interposer can couple IC dies with each other and with a circuit board.

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Views referred to as “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure. Further, where considered appropriate, reference labels have been repeated among the figures to indicate corresponding or analogous elements. In the figures:

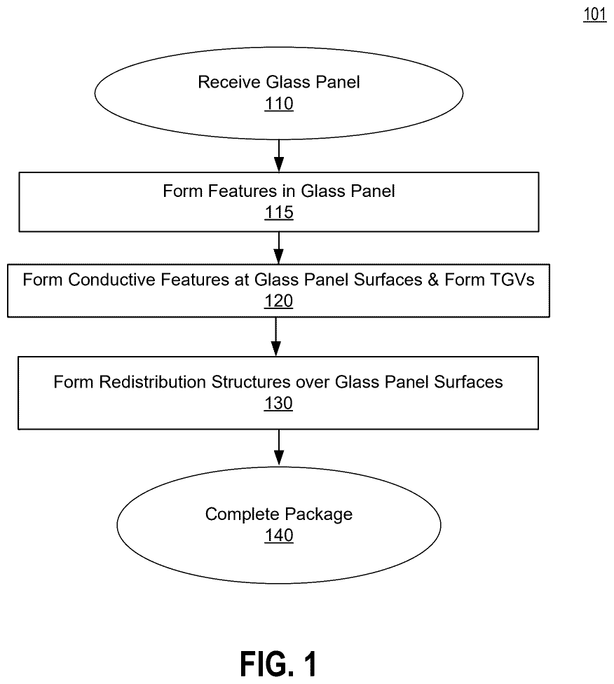

FIG. 1 illustrates a flow diagram of methods for forming an IC device structure with a glass-core substrate or an interposer, the glass core including a conductive trace having a portion within a trench on a surface of the glass and a portion above the surface, in accordance with some embodiments;

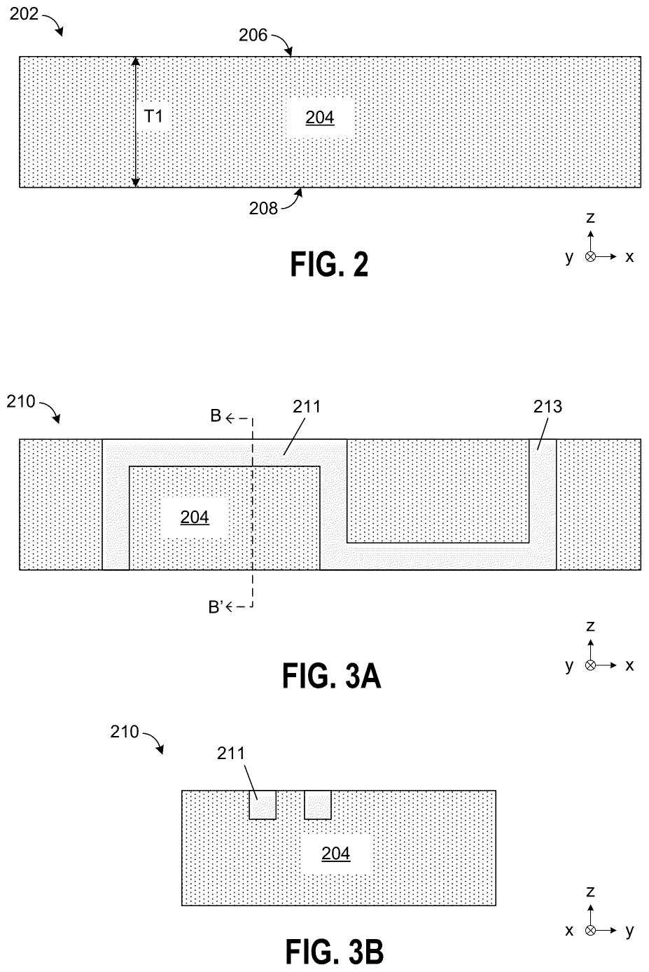

FIG. 2 is a cross-sectional view of a glass panel received at an initial stage of fabrication, in accordance with some embodiments;

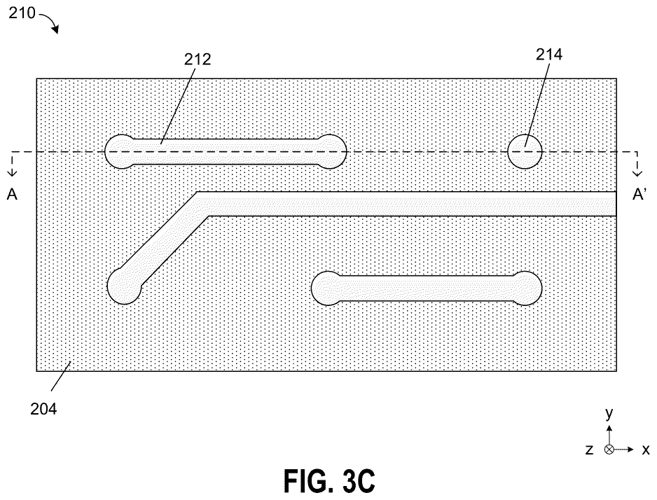

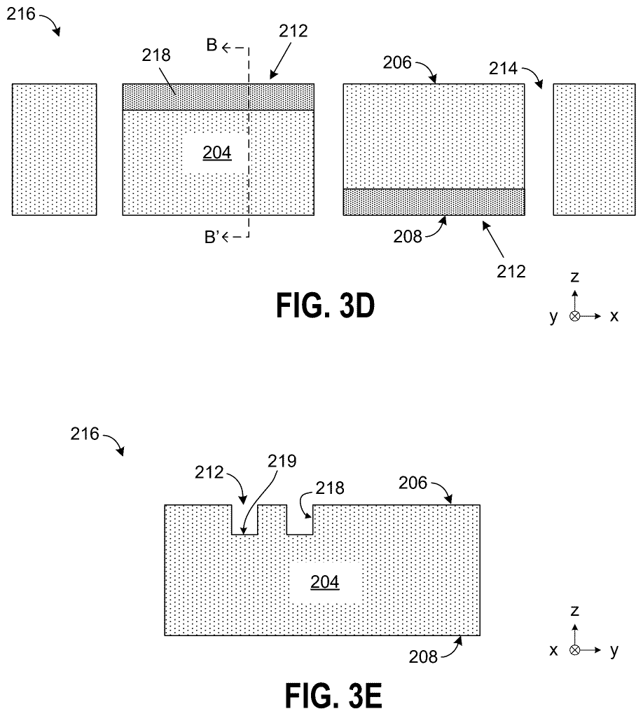

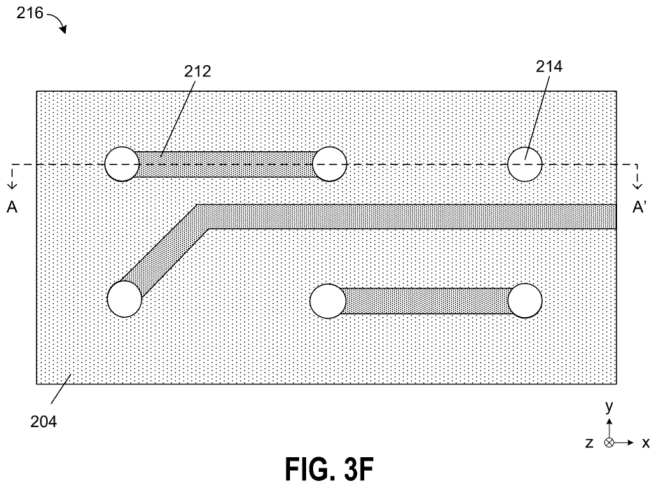

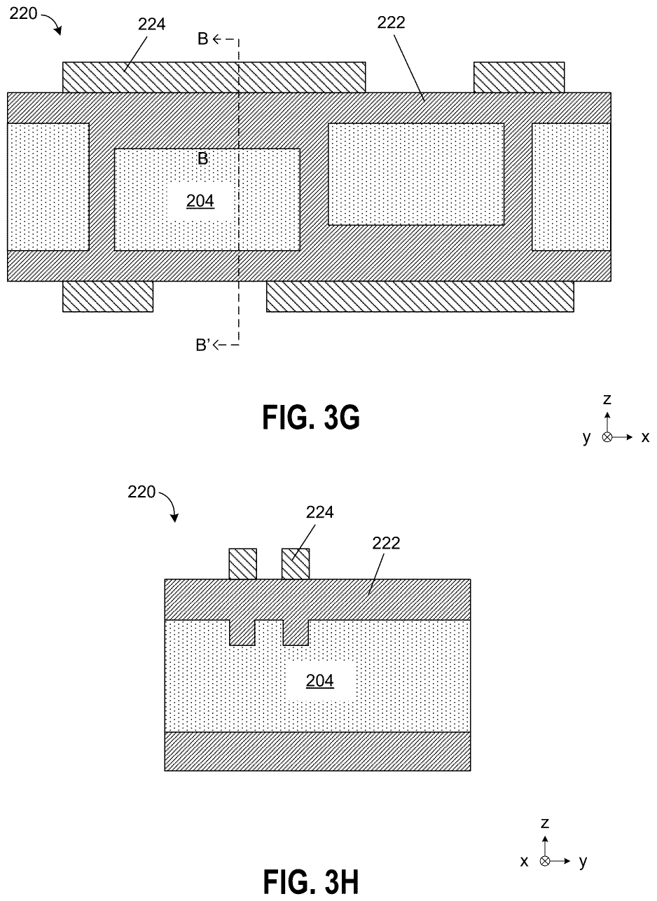

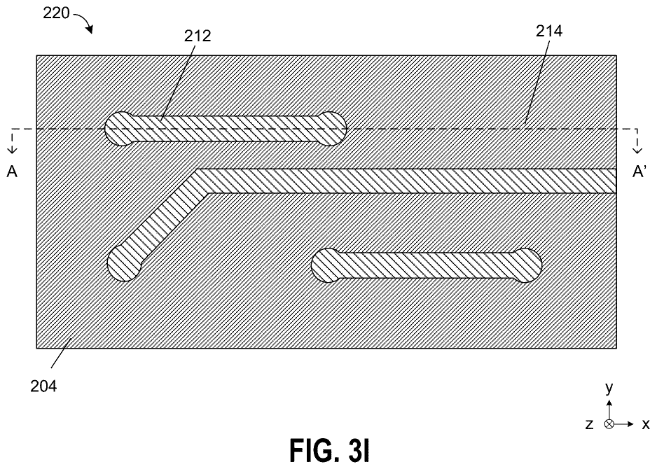

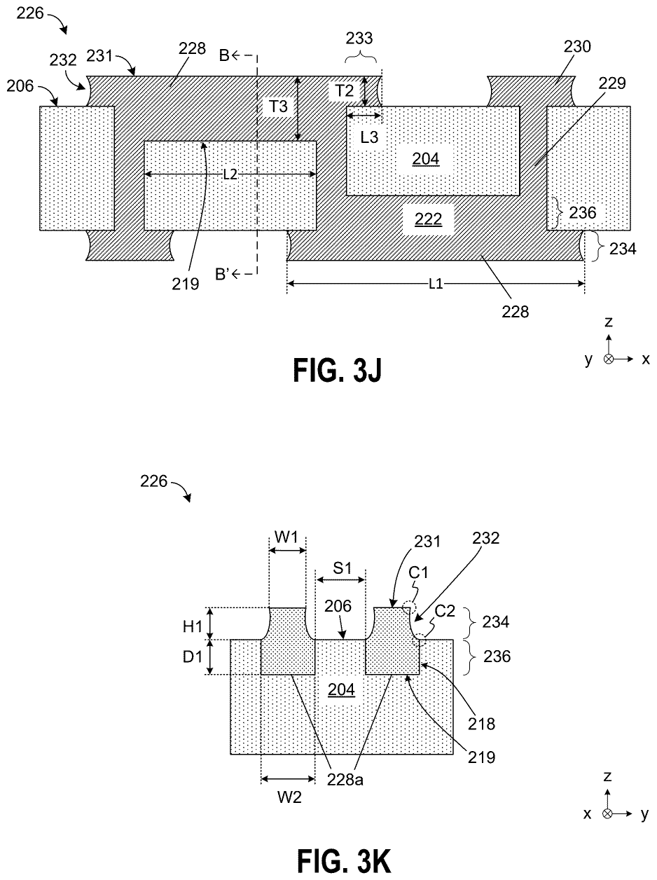

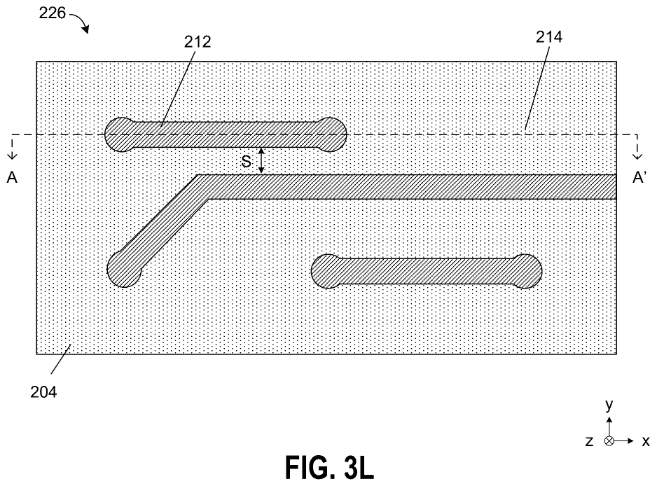

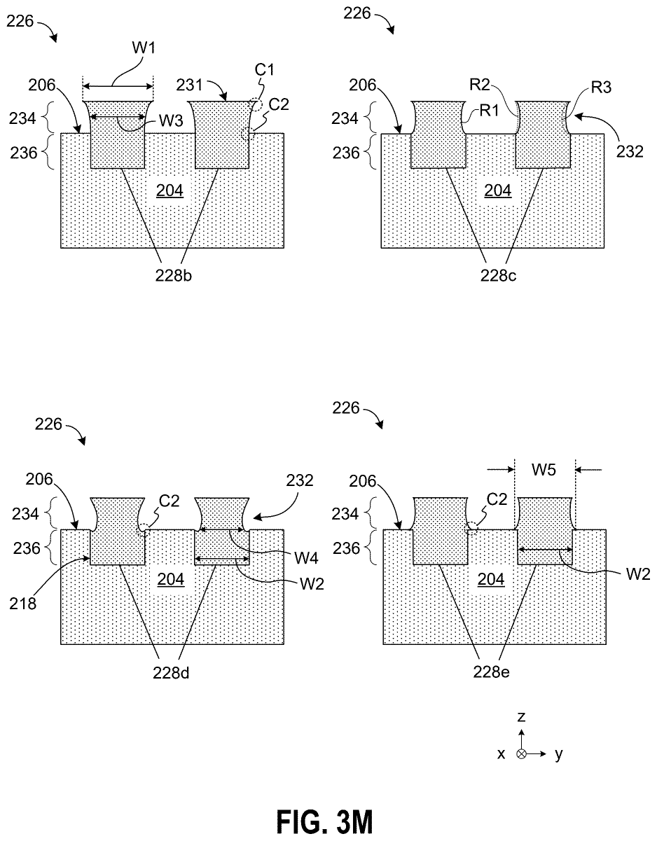

FIGS. 3A-3M are cross-sectional views of a glass panel evolving as operations in the methods illustrated in FIG. 1 are practiced, in accordance with some embodiments;

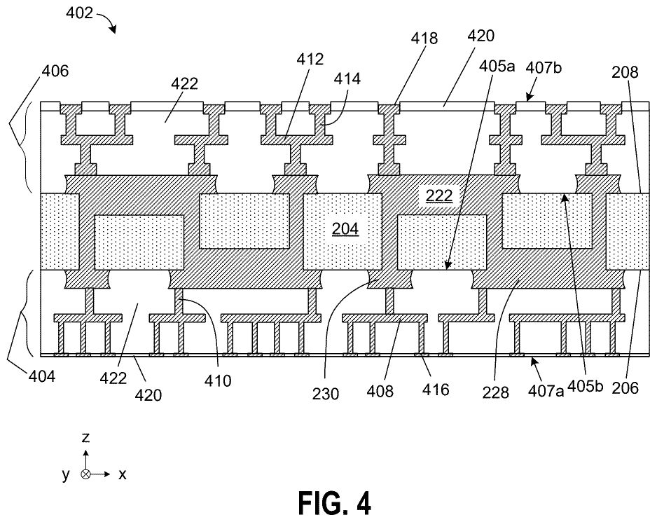

FIG. 4 is a cross-sectional view of a glass-core package substrate or interposer at a stage of fabrication of the methods illustrated in FIG. 1, in accordance with some embodiments;

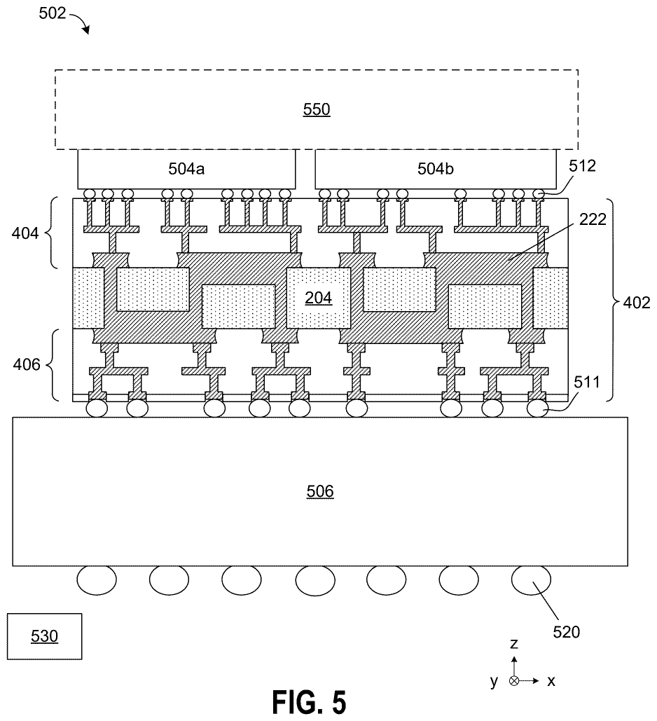

FIG. 5 illustrates a system at a stage of fabrication of the methods illustrated in FIG. 1 after one or more IC dies and a host component have been attached to the package substrate of FIG. 4, in accordance with some embodiments;

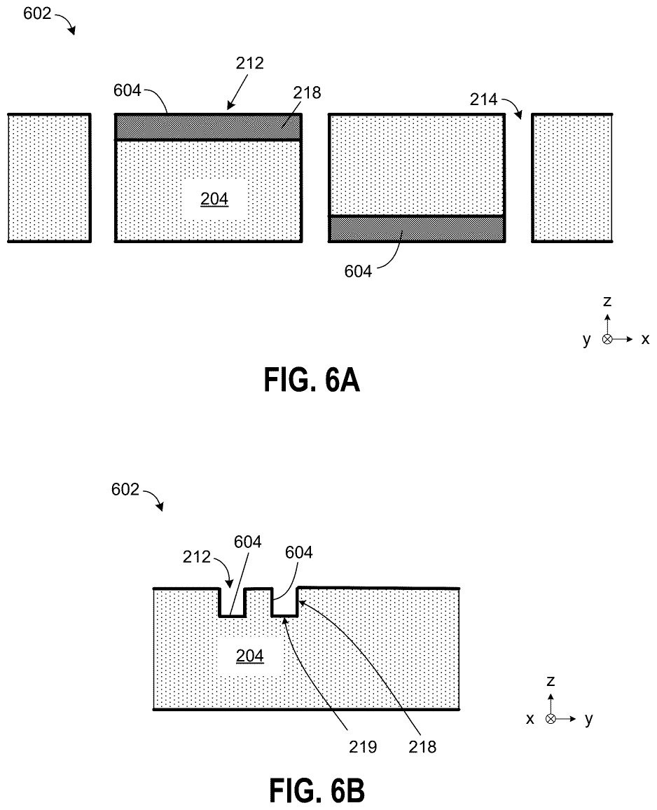

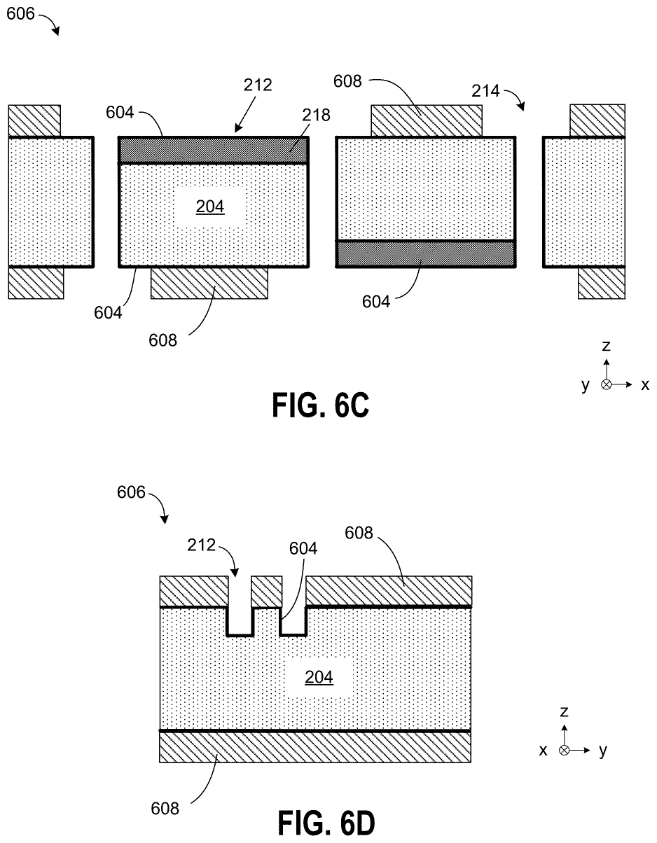

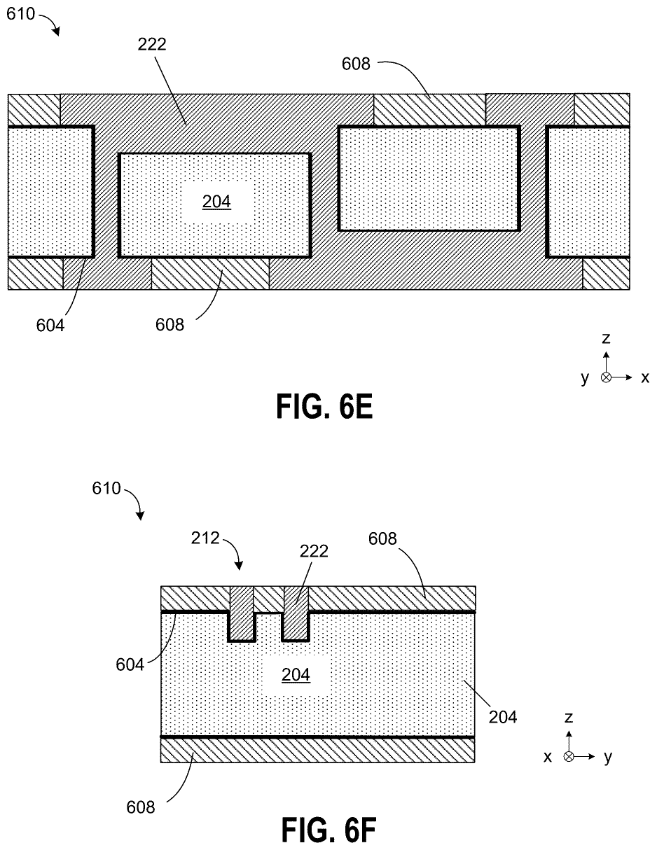

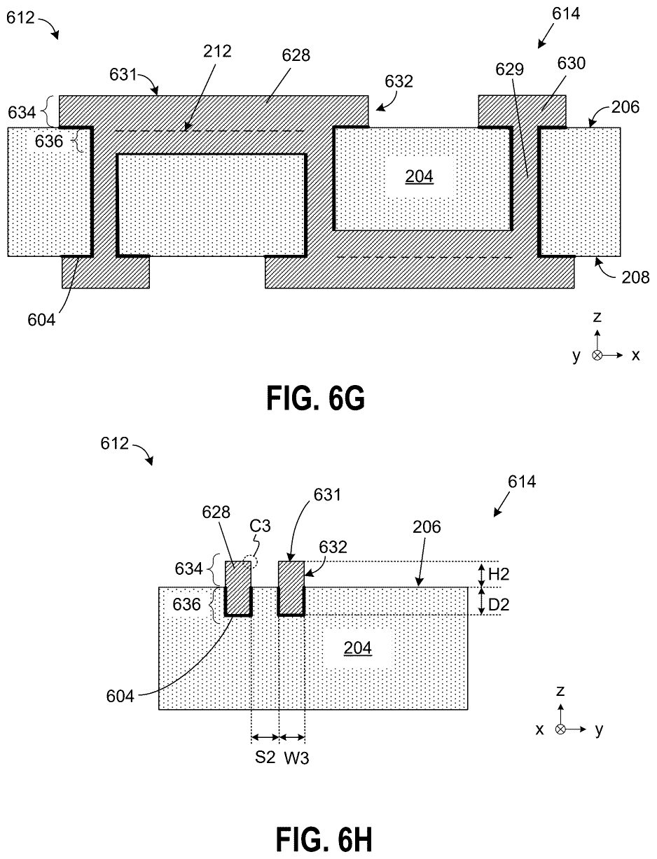

FIGS. 6A-6H are cross-sectional views of a glass panel evolving as operations in the methods illustrated in FIG. 1 are practiced, in accordance with some alternative embodiments;

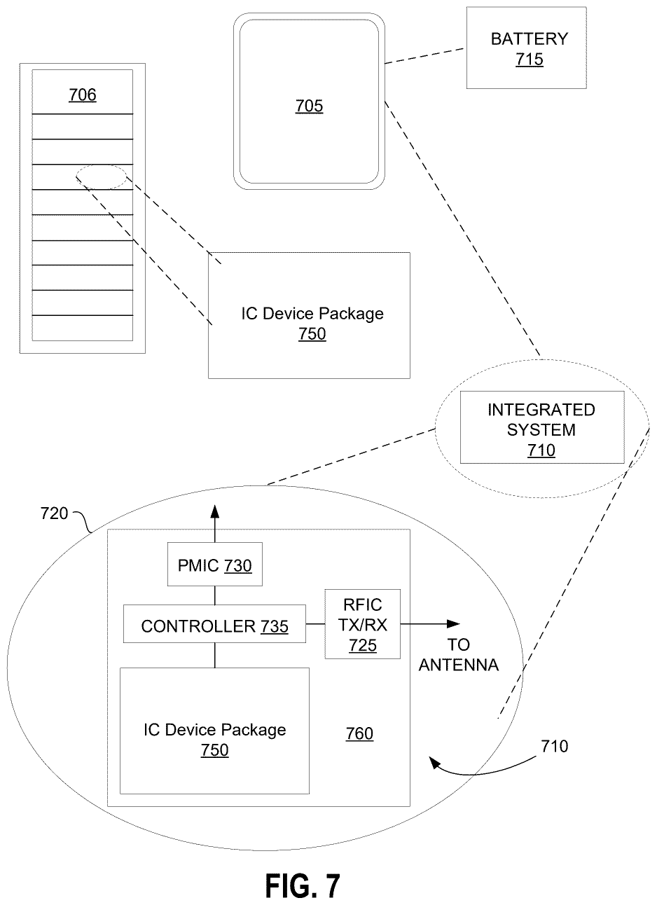

FIG. 7 illustrates a mobile computing platform and a data server machine employing one or more apparatus comprising an IC package with a substrate or an interposer having a glass core, the glass core including a conductive trace having a portion within a trench in the glass and a portion above the surface of the glass, in accordance with some embodiments; and

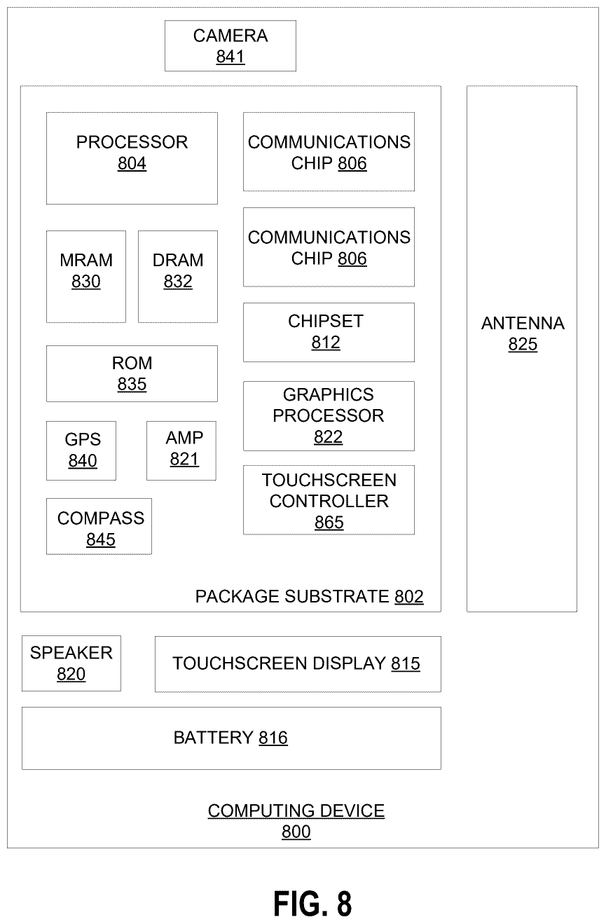

FIG. 8 is a functional block diagram of an electronic computing device, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. A “vertical” orientation is in the z-direction. A “lateral” orientation is in the x-or y-direction. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

With increasing miniaturization of circuitry in IC dies coupled with a package substrate or interposer, the desired number of connections between IC dies and the package substrate or interposer may increase. It may be desirable to provide a large number of conductive traces on the surface of a glass core. In addition, there may be a need to provide a significant amount of power to the IC dies, which may require connections capable of carrying relatively large currents. Electrical resistance is inversely proportional to the cross-sectional area of a wire. A conductive trace with a particular cross-sectional area will have a smaller resistance than another conductive trace with a smaller cross-sectional area. It may be desirable to provide conductive traces with relatively large cross-sectional areas.

More conductive traces can be placed on the surface of a glass core and the they can be made wider and taller. However, one challenge with this approach is that conductive traces on the surface of a glass core are required by design rules to be separated by a particular distance. As the height above the surface increases, the design rules may require larger spacing distances. Another challenge is that making conductive traces wider limits the number of conductive traces that can be placed on the surface of a glass core.

Embodiments are directed to an IC device structure with a glass-core substrate or an interposer, the glass core including a conductive trace having a portion within a trench on a surface of the glass and a portion above the surface. Embodiments are also directed to a self-aligned core patterning process. Advantages of the embodiments described herein are that conductive traces with a portion within a trench and a portion above the glass may have a higher aspect ratio than other conductive traces that are only on the glass surface. Another advantage of the conductive traces described herein is that they may have a larger cross-sectional area than conductive traces that are only on the glass surface, the increased thickness provided by the portion of the conductive trace within the trench giving the conductive traces described herein lower electrical resistance than conductive traces that are only on the glass surface. A further advantage of embodiments described herein is that package substrates or interposers with a glass core are more rigid and can accommodate more IC dies than substrates made from organic materials.

As illustrated in FIG. 1, a variety of fabrication methods may be practiced to form IC device package structures having one or more of the features described herein. FIG. 1 illustrates a flow diagram of methods for forming an IC device structure with a glass-core substrate or interposer, the glass core including a conductive trace having a portion within a trench on a glass surface and a portion above the surface, in accordance with some embodiments. Methods 101 begin at input 110 where a workpiece including a thickness of glass is received. The workpiece may be prepared upstream of methods 101 and may be in a large panel format, a wafer format, or the like. The workpiece received at input 110 may be patterned with a plurality of holes and trenches or the workpiece may not be patterned, e.g., as shown in FIG. 2.

FIG. 2 is a cross-sectional view of a glass panel 204 received at an initial stage of fabrication 202, in accordance with some embodiments. Advantages of fabricating IC device package structures upon glass are that the flatness and/or thickness control for a preform of glass is superior to that of starting substrates based on organic materials (e.g., epoxy), and the costs can be significantly lower than for monocrystalline materials (e.g., silicon). Glass 204 is a solid bulk material layer that may have been previously formed into any shape suitable for a packaging workpiece, such as rectangular. Glass 204 includes a first surface 206 and a second surface 208 opposite the first surface. Glass 204 has a thickness T1 that may vary with implementation, for example, to limit warpage while remaining thin enough to permit the formation of through vias and trenches at pitches as small as is enabled by the surface flatness of glass 204. In exemplary embodiments, thickness T1 is advantageously 0.1 mm to 3.0 mm.

Although not depicted, one or more material layers may clad either or both of the first surface 206 or second surface 208 of glass 204 so that glass 204 is a bulk or core layer of a multi-layered substrate. Exemplary cladding materials include inorganic materials such as silicon nitride (SiNx) or silicon oxynitride (SiOxNy). In other embodiments, a silicon layer (polycrystalline or monocrystalline) may clad one or both sides of glass 204. Organic material layers, such as polymer dielectric materials, may also clad one or more sides of glass 204. Hence, while glass 204 is advantageously substantially free of organic materials (e.g., no adhesives, etc.), a workpiece at stage of fabrication 202 may include organic material within a substrate stack that includes glass 204.

Glass 204 is advantageously predominantly silicon and oxygen. In some embodiments, glass 204 comprises at least 23 percent silicon and at least 26 percent oxygen, by weight (i.e., wt. %). Glass 204 may further include one or more additives, such as, Aluminum, Boron, Magnesium, Calcium, Barium, Tin, Sodium, Potassium, Strontium, Phosphorus, Zirconium, Lithium, Titanium, or Zinc. In some embodiments where glass 204 comprises at least 23 wt. % Si and at least 26 wt. % O, glass 204 further comprises at least 5 wt. % Al. Additives within glass 204 may form suboxides (A2O) monoxides (AO), binary oxides (AO2), ternary oxides (ABO3), and mixtures thereof. For example, glass 204 may comprise AlOx (e.g., Al2O3), BOx (e.g., B2O3), MgOx (e.g., MgO), CaOx (e.g., CaO), SrOx (e.g., SrO), BaOx (e.g., BaO), SnOx (e.g., SnO2), NaOx (e.g., Na2O), KOx (e.g., K2O), POx(e.g., P2O3), ZrOx (e.g., ZrO2), LiOx (e.g., Li2O), TiOx (e.g., TiO2), or ZnOx (e.g., ZnO2). Depending on chemical composition, glass 204 may therefore be referred to as silica, fused silica, aluminosilicate, borosilicate, or alumino-borosilicate, for example.

Glass 204 is advantageously a bulk material of substantially homogeneous composition in contrast to a composite material that may merely comprise glass fillers and/or fibers. Although glass 204 is substantially amorphous in some embodiments, glass 204 may also have other morphology or microstructure, such as polycrystalline (e.g., nanocrystalline).

Returning to FIG. 1, methods 101 continue at block 115 where features are formed in un-patterned glass 204. Example features include through holes or openings in the glass, and trenches or channels on one or both surfaces of the glass. The features may be fabricated with any process known to be suitable for bulk glass. In some embodiments, block 115 entails laser ablation, a glass etch process (laser-assisted, or otherwise), or any other technique known to be suitable for forming features within or through a thickness of glass at a desired x-y size (diameter, or width and length), z-size (depth), and feature pitch.

FIGS. 3A and 3B are cross-sectional views of glass panel 204 at a stage of fabrication 210 after features have been written with laser radiation in the glass panel, in accordance with some embodiments. FIG. 3C is a plan view of glass panel 204 at a stage of fabrication 210. The cross-sectional view in FIG. 3A is taken along the line A-A′ (shown in FIG. 3C). The cross-sectional view in FIG. 3B is taken along the line B-B′ (shown in FIG. 3A). In the example illustrated in FIGS. 3A-3C, locations 211 for trenches 212 and locations 213 for through holes 214 have been written with laser radiation that alters one or more properties of glass 204. In some embodiments, the laser radiation is pulsed (e.g., at a femtosecond rate), which renders the portions of glass 204 that are exposed to the radiation more susceptible to etching by chemical etchants. The laser patterning process at 210 may therefore both define locations and dimensions of trenches 212 and through holes 214.

FIGS. 3D and 3E are cross-sectional views of glass panel 204 at a stage of fabrication 216 after features have been etched in the glass panel, in accordance with some embodiments. FIG. 3F is a plan view of glass panel 204 at a stage of fabrication 216. As illustrated in FIGS. 3D, 3E, and 3F, the etch process forms trenches 212 and through holes 214. While trenches 212 are formed at both first surface 206 and second surface 208 in the illustrated example, in other examples, trenches 212 may be formed at only one of the surfaces. The dimensions of through holes 214 and trenches 212 may vary with implementation, as described below. Any suitable wet or dry etching process known in the art may be employed at stage of fabrication 216.

The trenches 212 include sidewalls 218. In some embodiments, sidewalls 218 are substantially straight or planar. In some examples, sidewalls 218 are substantially orthogonal to surfaces 206, 208 as illustrated in FIG. 3E. In other examples, sidewalls 218 are may have a positive taper with respect to one of the surfaces 206, 208, e.g., the trench is wider at the surface than it is at a bottom surface 219 of the trench. In yet other examples, sidewalls 218 are may have a negative taper with respect to one of the surfaces 206, 208, e.g., the trench is narrower at the surface than it is at the bottom of the trench.

Returning to FIG. 1, methods 101 continue at block 120 where conductive features are formed at one or both surfaces of glass panel and TGVs are formed. Conductive features may include traces or lines. Conductive features and TGVs may be formed using a subtractive etch process, a semi-additive process, or any other suitable process. FIGS. 3G-3L illustrate a subtractive etch process for fabricating conductive features and TGVs, in accordance with some embodiments. FIGS. 6A-6H illustrate a semi-additive process for fabricating conductive features and TGVs, in accordance with some embodiments.

FIGS. 3G and 3H are cross-sectional views of glass panel 204 at a stage of fabrication 220 after deposition of a conductive material 222 and after application of photoresist 224 over the conductive material 222, in accordance with some embodiments. FIG. 3I is a plan view of glass panel 204 at a stage of fabrication 220. As illustrated in FIGS. 3G-3I, the conductive material 222 covers both surfaces 206, 208 and fills the though holes 214 and the trenches 212. The conductive material 222 may be any conductive material, including but not limited to metals, such as copper, aluminum, gold, titanium, nickel, tungsten, silver, zirconium, cobalt, and alloys thereof. Conductive material 222 may be deposited by any suitable process known in the art. In some examples, conductive material 222 is formed by sputtering copper or another suitable metal over surfaces 206, 208.

In FIGS. 3G-3I, the photoresist 224 has been applied at selected locations over the conductive material 222 on surfaces 206, 208 and over conductive material 222. Any suitable photoresist may be used. In some embodiments, photoresist 224 is a dry film resist. Photoresist 224 may be formed using any suitable techniques. For example, photoresist 224 may be applied using vacuum lamination or hot lamination techniques. In addition, in FIGS. 3G-3I, the photoresist 224 may be applied over entire surfaces and then patterned by a photolithographic process to form openings where conductive material 222 will be removed in a subsequent operation to form conductive features, e.g., conductive traces 228, at particular locations on surfaces 206, 208.

FIGS. 3J, 3K and 3M are cross-sectional views of glass panel 204 at a stage of fabrication 226 after unmasked portions of conductive material 222 and photoresist 224 have been removed, exposing conductive traces 228 and conductive features 230, in accordance with some embodiments. FIG. 3L is a plan view of glass panel 204 at the stage of fabrication 226. Cross sections of TGVs 229 may be seen in FIG. 3J. Conductive traces 228 comprise a first portion 236 within trench 212 and a second portion 234 above the surface of the glass 204, e.g., first surface 206 or second surface 208. The conductive traces 228 and conductive features 230 have upper surfaces 231 and sidewalls 232 extending above surface 206. In the example illustrated in FIGS. 2J-L, the conductive traces 228 and conductive features 230 have been formed using a subtractive etch process that etches the conductive material 222 through a lithographically defined etch mask of photoresist. In alternative embodiments, conductive traces 228 and conductive features 230 may be formed using a semi-additive process, for example, as described elsewhere herein.

While conductive traces 228 are generally within trenches 212, a segment 233 (also referred to as portion) of a conductive trace 228 may extend a lateral length L3 away from a trench 212 or TGV 229. For example, the segment 233 is over first surface 206, but not over a trench or TGV. As such, a conductive trace 228 may comprise a first thickness T2 away from the trench and a second thickness T3 over trench 212. The first thickness T2 is between the surface 206 and upper surface 231 of conductive trace 228. The second thickness T3 is between bottom surface 219 of the trench and the upper surface 231. The second thickness T3 is greater than the first thickness T2. In some examples, length L3 is greater than width W1 of a conductive trace or a width W2 of a trench, however, this is not essential.

Conductive traces 228 have a length L1 that extends laterally, a width W1 at the upper surface 231 of conductive trace 228, and a width W2. The width W2 may be either proximate the glass surface, e.g., first surface 206, or at the bottom surface 219 of trench 212. The width W1 may be at upper surface 231 of the conductive trace 228. In embodiments, width W1 may be between 30 and 50 microns. In some examples, widths W1 and W2 are approximately equal. In some examples, width W1 may be slightly narrower than W2, e.g., five to ten percent narrower. In some examples, width W1 may be slightly wider than W2, e.g., five to ten percent wider.

In embodiments, a conductive trace 228 extends a laterally length L1, wherein L1 is greater than a width W1 or W2 of the conductive trace. In some examples, the conductive traces 228 have lateral dimensions L1 of 40 microns to 10 mm or greater. As illustrated in FIGS. 3J and 3L, a portion of a conductive trace 228 may be over a TGV and another portion may not be over a TGV. For example, conductive trace 228 extends a laterally length L2 that is not over a TGV. In some examples, length L2 of a conductive trace extends between first and second TGVs. In some examples, length L2 of a conductive trace extends between a TGV and a conductive feature other than a TGV (not illustrated in FIG. 3J) within a routing structure over a surface of glass 204, e.g., first surface 206 or second surface 208. In some examples, a conductive trace 228 extends without spanning a location where a TGV (or other conductive feature within the glass 204) meets the first surface 206. For example, a conductive trace 228 may extend between first and second features (not illustrated in FIG. 3J or 3L) on first surface 206. As another example, a conductive trace 228 may extend between first and second features in a routing structure over a first surface 206. As mentioned, a conductive trace 228 may also extend a length L3 that is not within or over a trench 212.

As illustrated in FIG. 3K, a conductive trace 228 may have a height H1 (e.g., z-height) above first surface 206 (or second surface 208) of between 5 to 75 microns. A conductive trace 228 may extend to a depth D1 (e.g., z-height) below first surface 206. Depth D1 may be between 5 microns and 40-50 percent of glass thickness T1. In some examples, conductive traces 228 may extend a depth D1 between 0.05 mm to 1.5 mm. As mentioned, conductive trace 228 may have a width W1 or W2. When two conductive traces 228 are adjacent one another, a minimum spacing S1 is required between the conductive traces. The minimum spacing S1 required between adjacent conductive traces 228 also applies to conventional conductive traces. For example, two or more adjacent conventional conductive traces on a surface of a glass core or within a dielectric in a redistribution structure may be required to have minimum spacing S1 between traces. An advantage of the embodiments described herein is that adjacent conductive traces 228 of a particular width can be thicker than adjacent conventional conductive traces having the same width because of the added depth within the glass panel. Accordingly, conductive traces 228 may provide lower electrical resistance than conventional conductive traces. Lower electrical resistance is especially advantageous for conductive traces 228 that carry power signals.

In embodiments in which a subtractive etch process is employed, the minimum spacing S1 between adjacent conductive traces 228 may be 1-2 times the height H1. Accordingly, in some examples, height H1 is in a range of 15-25 microns and S1 is in a range of 30-50 microns.

Depending on the process practiced, sidewalls 232 may have a profile with a concave curvature or scalloped shape, indicative of a subtractive etch process. Conductive traces 228 may have a first corner C1 between upper surface 231 and a sidewall 232. In addition, there may be a second corner C2 where sidewall 232 meets first surface 206 (or second surface 208). Conductive traces 228a, illustrated in FIG. 3K, include a first corner C1 without significant undercut or over hang at first corner C1, according to some embodiments. Second corner C2 of conductive trace 228a curves to meet first surface 206.

FIG. 3M illustrates additional examples of profiles of sidewalls 232 of conductive traces fabricated with a subtractive etch process, according to some embodiments. Conductive traces 228b, illustrated in FIG. 3M, include a first corner C1 with undercut or over hang at first corner C1. Second corner C2 of conductive trace 228b meets first surface 206 with a vertically straight or planar profile.

Conductive traces 228c illustrate sidewalls 232 with a concave curved profile defined by radius of curvature R1. In some examples, a sidewall may curve to greater, as illustrated by radius of curvature R3, or by lesser extent, as illustrated by radius of curvature R2. In FIG. 3M, dotted lines show sidewall profiles with greater or lesser curvature. Conductive traces 228c exhibit varying degrees of undercut at first corner C1.

Conductive traces 228d have a width W4 at first surface 206 where first portion 236 meets the second portion 234. The width W4 is less than the width W2 of trench 212 at either first surface 206 or bottom surface 219. The second corner C2 of conductive traces 228d may have a depression or trough between the vertical extent of sidewall 232 and first surface 206, indicating removal of a small portion of the conductive material 222 within trench 212, i.e., removal of conductive material within first portion 236.

Conductive traces 228e have a width W5 at first surface 206, where width W5 is greater than width W2 of trench 212. The second corner C2 of conductive traces 228d may include a portion extending laterally that overlaps the width W2 of trench 212.

Referring again to FIG. 1, methods 101 continue at block 130 where redistribution structures are formed over a surface of glass panel 204. FIG. 4 is a cross-sectional view of glass panel 204 at a stage of fabrication after formation of redistribution structures 404 and 406, in accordance with some embodiments. The structure illustrated in FIG. 4 may be a package substrate 402, in accordance with some embodiments. In other embodiments, the structure illustrated in FIG. 4 may be an interposer. Package substrate 402 includes a glass panel 204 with conductive traces 228 and conductive features 230 that is similar to the example depicted in FIGS. 3J-3L. (The orientation of glass panel 204 is reversed from FIG. 3J.) Redistribution structure 404 is over first surface 206 and comprises one or more layers of package metallization that include multiple front-side line metallization 408 and front-side via metallization 410 between the line metallization levels. Redistribution structure 406 is over second surface 208 and comprises one or more layers of package metallization that include multiple back-side line metallization 412 and back-side via metallization 414 between the line metallization levels. Via metallization may vertically interconnect line metallization with conductive traces 228 and conductive features 230. In some examples, package substrate 402 may have only one redistribution structure on one surface.

Redistribution structures 404 and 406 comprise first surfaces 405a, 405b proximate glass panel 204 and second surfaces 407a, 407b opposite the first surfaces, which may be referred to as an “outer” surface. As depicted in FIG. 4, interconnects 416, 418 (also referred to as contact pads) have been formed at outer surfaces of redistribution structures 404 and 406. The interconnects 416, 418 may be separated by the solder resist material 420. Via metallization vertically interconnects line metallization, conductive traces 228, and conductive features 230 with interconnects 416, 418 at the outer surfaces. The conductive traces 228 and conductive features 230 together with metallization features in the redistribution structures may be used to route electrical signals interconnects 416, 418. For example, the conductive traces 228 may be used as part of a network for routing power electrical signals from interconnects on one surface to interconnects on an opposite surface, or to and from an electrical component within the glass panel 204. Via metallization 410, 414 and line metallization 408, 412 within package substrate 402 may have been formed with an additive or semi-additive process, for example. Via metallization 410, 414 and line metallization 408, 412 may comprise copper. However, other conductive materials are also possible.

Package substrate metallization is embedded within one or more layers of package substrate insulator 422. In exemplary embodiments, package substrate insulator 422 comprises an organic dielectric material (e.g., comprising a polymer). Package substrate insulator 422 may comprise an epoxy resin, phenolic-glass, or a resinous film such as the GX-series films commercially available from Ajinomoto Fine-Techno Co., Inc.). Exemplary epoxy resins include an acrylate of novolac such as epoxy phenol novolacs (EPN), or epoxy cresol novolacs (ECN). In some specific examples, package substrate insulator 422 is a bisphenol-A epoxy resin, for example including epichlorohydrin. In other examples, package substrate insulator 422 includes bisphenol-F epoxy resin (with epichlorohydrin). In other examples, package substrate insulator 422 includes aliphatic epoxy resin, which may be monofunctional (e.g., dodecanol glycidyl ether), difunctional (butanediol diglycidyl ether), or have higher functionality (e.g., trimethylolpropane triglycidyl ether). In still other examples, package substrate insulator 422 includes glycidylamine epoxy resin, such as triglycidyl-p-aminophenol (functionality 3) and N, N, N, N-tetraglycidyl-bis-(4-aminophenyl)-methane (functionality 4).

Returning to FIG. 1, methods 101 continue at block 140 where an IC device package 502 is completed, in accordance with some embodiments. FIG. 5 is a cross-sectional view of an IC device package 502 at a stage of fabrication after one or more IC dies and a host component have been attached to a package substrate, in accordance with some embodiments. As illustrated in FIG. 5, IC dies 504a and 504b have been attached to a surface of package substrate 402 and the package substrate 402 has been attached to a host component 506.

In some embodiments, IC dies 504a and 504b may be attached to interconnects 416 of package substrate 402 by solder features 512. In some embodiments, interconnects 416 are directly bonded to conductive features (not shown) of IC dies 504a and 504b using a hybrid bonding technique. When hybrid bonding is employed, surface metal features embedded within an insulator of one IC die are directly fused to surface metal features embedded within an insulator of another die (or in this case within redistribution structure 404). The hybrid bonded interface between the dies may include both metallurgically interdiffused metals and chemically bonded insulators.

The IC dies 504a and 504b may comprise circuitry to perform any desired functionality. For example, any of IC dies 504a and 504b may be a logic circuit, a power management integrated circuit, a transmitter, a receiver, a memory controller, a communications controller, a controller, a processor, an application specific integrated circuit (ASIC), or a memory. Any of any of IC dies 504a and 504b may be a photonic integrated circuit (PIC) or include optical or photonic elements. IC device package 502 may be coupled with a power supply 530. The power supply 530 may be coupled with IC dies 504a and 504b via host component 506 and package substrate 402 with a glass core. Power may be provided to IC dies 504a and 504b from power supply 530 by a network comprising conductive structures within package substrate 402, e.g., conductive traces 228, conductive features 230, and metallization features within redistribution structures 404, 406.

Package substrate 402 may be attached to host component 506 by reflowing first level interconnects (FLI) 511. In exemplary embodiments, FLI interconnects 511 are solder (e.g., SAC) microbumps although other interconnect features are also possible. In some embodiments, host component 506 is predominantly silicon. Host component 506 may also comprise one or more alternative materials known to be suitable as interposers or package substrates (e.g., an epoxy preform, cored or coreless laminate board, etc.). Host component 506 may include one or more metallized redistribution levels (not depicted) embedded within a dielectric material. Host component 506 may also include one or more IC die embedded therein. In embodiments in which package substrate 402 is an interposer, the interposer may be attached via redistribution structure 406 to one or more IC die in lieu of host component 506.

In other embodiments, host component 506 includes second level interconnects (SLI) 520. SLI 520 may comprise any solder (ball, bump, etc.) suitable for a given host board architecture (e.g., surface mount FR4, etc.). As illustrated in dashed line, one or more heat spreaders and/or heat sinks 550 may be further coupled to IC dies 504a and 504b, which may be advantageous, for example, where IC dies 504a, 504b comprise one or more CPU cores or other circuitry of similar power density.

IC device package 502 includes package substrate 402. Package substrate 402 comprises a glass panel having a trench on a surface and conductive traces comprising a first portion within the trench and a second portion above the surface. In the examples presented above, the conductive traces 228 of package substrate 402 are fabricated with a subtractive etch process. In these examples, the sidewall profiles of conductive traces 228 have a concave curvature indicative of the subtractive etch process. However, in other examples, the conductive traces 228 may not have sidewalls 232 with inward curving profiles. In other examples, described below, sidewalls 232 may have a substantially straight or planar profile indicative of a semi-additive process.

Returning to FIG. 1, at block 120 of methods 101 conductive features are formed at one or both surfaces of glass panel and TGVs are formed. FIGS. 6A-6H illustrate a semi-additive process for forming conductive traces on one or both surfaces of a glass panel and forming TGVs, in accordance with some embodiments. FIGS. 6A and 6B illustrate a stage of fabrication 602 after a seed layer 604 has been deposited on surfaces of glass panel 204. Stage of fabrication 602 may be after features have been formed in a glass panel. For example, the stage of fabrication 602 illustrated in FIG. 6A and 6B may be after stage of fabrication 216, illustrated in FIGS. 3D and 3E. In some examples, seed layer 604 is a thin film of conductive material comprising copper, gold, silver or other suitable metal. Seed layer 604 is deposited on surfaces 206, 208, on surfaces of though holes 214, and on surfaces of trenches 212, including sidewalls 218 and bottom surfaces 219 of trenches 212.

FIGS. 6C and 6D are cross-sectional views of glass panel 204 at a stage of fabrication 606 after photoresist 608 has been deposited over surfaces of glass panel 204 and patterned. The patterned photoresist serves as plating mask for a subsequent stage of fabrication. The photoresist 608 may be patterned by a photolithographic process and includes openings at locations designated for conductive traces and other conductive features. Photoresist 608 may be any suitable photoresist material known in the art. Similarly, the photolithographic process may be any suitable photolithographic process known in the art.

FIGS. 6E and 6F are cross-sectional views of glass panel 204 at a stage of fabrication 610 after electroplating conductive material 222 over exposed surfaces of glass panel 204, including surfaces 206, 208, as well as surfaces of though holes 214 trenches 212. Conductive material 222 is plated on seed layer 604 in openings in the photoresist 608 plating mask.

FIGS. 6G and 6H are cross-sectional views of glass panel 204 at a stage of fabrication 612 after photoresist removal and seed layer etch processes have been performed to expose conductive traces 628 and conductive features 630, in accordance with some embodiments. FIGS. 6G and 6H illustrate a glass core structure 614 comprising conductive traces 628 that include a portion within a trench, conductive features 630, and TGVs. The photoresist 608 and exposed portions of seed layer 604 may be removed using any suitable processes known in the art. Conductive traces 628 comprise a first portion 636 within trench 212 and a second portion 634 above the surface of the glass 204, e.g., surface 206, 208. The conductive traces 628 and conductive features 630 have upper surfaces 631 and sidewalls 632 extending above surface 206. Second portions 634 comprise the sidewalls 632. The sidewalls 632 comprise a profile that is substantially vertical or which has a slope of less than 10° from the vertical, indicative of a semi-additive patterning process. Conductive traces 228 comprise an upper corner C3 between upper surface 631 and a sidewall 632. In some examples, the upper corner C3 may be rounded over (not illustrated in FIG. 6H), indicative of a semi-additive patterning process. Similar to conductive traces 228, conductive traces 628 may extend extending laterally a length, wherein the length is greater than a width of the conductive trace. Cross sections of TGVs 629 may be seen in FIG. 6G.

As illustrated in FIG. 6H, a conductive trace 628 may have a height H2 (e.g., z-height) above first surface 206 (or second surface 208) of between 5 to 75 microns. A conductive trace 628 may extend to a depth D2 (e.g., z-height) below first surface 206. Depth D2 may be between 5 microns and 40-50 percent of glass thickness T1. In some examples, conductive traces 628 may extend a depth D2 between 0.05 mm to 1.5 mm. Conductive trace may have a width W3. When two conductive traces 628 are adjacent one another, a minimum spacing S2 is required between the conductive traces. The same minimum spacing S2 required between adjacent conductive traces 628 may also apply to conventional conductive traces. An advantage of the embodiments described herein is that adjacent conductive traces 628 of a particular width W3 can be thicker than adjacent conventional conductive traces having the same width W3 because of the added depth within the glass panel. Accordingly, conductive traces 628 may provide lower electrical resistance than conventional conductive traces. Lower electrical resistance is especially advantageous for conductive traces 628 that carry power signals. In embodiments in which a semi-additive process is used, the minimum spacing S2 between adjacent conductive traces 628 may be 0.25-0.50 times the height H2. Accordingly, in some examples, height H2 is in a range of 15-25 microns and S2 is in a range of 3.50-13 microns.

A redistribution structure may be formed over one or both of surfaces 206, 208 of glass core structure 614 to form a package substrate or an interposer in a like manner as described with reference to FIG. 4 and package substrate 402. A package substrate comprising glass core structure 614 may be included in an IC device package, such as IC device package 502 as described with reference to FIG. 5, in accordance with some embodiments. As such, an IC device package may include one or more IC dies and a host component attached to a package substrate comprising a glass core structure 614 comprising redistribution structures, in accordance with some embodiments. In some embodiments, an IC device package may include one or more IC dies attached to an interposer comprising a glass core structure 614 comprising redistribution structures.

FIG. 7 illustrates a mobile computing platform and a data server machine employing one or more apparatus comprising an IC device package 750 (or an interposer) with a substrate having a glass core, the glass core including a conductive trace having a portion within a trench in the glass and a portion above the surface of the glass, for example as described elsewhere herein. Server machine 706 may be any commercial server, for example including any number of high-performance computing platforms disposed within a rack and networked together for electronic data processing. The mobile computing platform 705 may be any portable device configured for each of electronic data display, electronic data processing, wireless electronic data transmission, or the like. For example, the mobile computing platform 705 may be any of a tablet, a smart phone, laptop computer, etc., and may include a display screen (e.g., a capacitive, inductive, resistive, or optical touchscreen), a chip-level or package-level integrated system 710, and a battery 715.

Whether disposed within the integrated system 710 illustrated in the expanded view 720, or as a stand-alone package within the server machine 706, the IC device package 750 (or an interposer) with a substrate having a glass core, the glass core including a conductive trace having a portion within a trench in the glass and a portion above the surface of the glass, as described elsewhere herein. IC device package 750 may be further coupled to a host substrate 760, along with, one or more of a power management integrated circuit (PMIC) 730, RF (wireless) integrated circuit (RFIC) 725 including a wideband RF (wireless) transmitter and/or receiver (TX/RX) (e.g., including a digital baseband and an analog front-end module further comprises a power amplifier on a transmit path and a low noise amplifier on a receive path), and a controller 735. PMIC 730 may perform battery power regulation, DC-to-DC conversion, etc., and so has an input coupled to battery 715 and with an output providing a current supply to other functional modules. As further illustrated, in the exemplary embodiment, RFIC 725 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

FIG. 8 is a functional block diagram of an electronic computing device 800, in accordance with an embodiment of the present invention. The computing device may be found inside mobile computing platform 705 or server machine 706, as described elsewhere herein. Device 800 further includes a package substrate 802 hosting a number of components, such as, but not limited to, a processor 804 (e.g., an applications processor). Processor 804 may be physically and/or electrically coupled to package substrate 802. In general, the term “processor” or “microprocessor” may refer to any device or portion of a device that processes electronic data from registers and/or memory to transform that electronic data into other electronic data that may be further stored in registers and/or memory. In some embodiments, the package substrate 802 may be an IC device package with a substrate having a glass core, the glass core including a conductive trace having a portion within a trench in the glass and a portion above the surface of the glass, as described elsewhere herein. In some examples, one or more of the components of computing device 800 includes an interposer with a substrate having a glass core, the glass core including a conductive trace having a portion within a trench in the glass and a portion above the surface of the glass, as described elsewhere herein.

In various examples, one or more communication chips 806 may also be physically and/or electrically coupled to the package substrate 802. In further implementations, communication chips 806 may be part of processor 804. Depending on its applications, computing device 800 may include other components that may or may not be physically and electrically coupled to package substrate 802. These other components include, but are not limited to, volatile memory (e.g., DRAM 832), non-volatile memory (e.g., ROM 835), flash memory (e.g., NAND or NOR), magnetic memory (MRAM 830), a graphics processor 822, a digital signal processor, a crypto processor, a chipset 812, an antenna 825, touchscreen display 815, touchscreen controller 865, battery 816, audio codec, video codec, power amplifier 821, global positioning system (GPS) device 840, compass 845, accelerometer, gyroscope, speaker 820, camera 841, and mass storage device (such as hard disk drive, solid-state drive (SSD), compact disk (CD), digital versatile disk (DVD), and so forth), or the like.

Communication chips 806 may enable wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 806 may implement any of a number of wireless standards or protocols. As discussed, computing device 800 may include a plurality of communication chips 806. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

Example 1: An apparatus comprising: a glass panel comprising a surface, a trench in the surface, and a routing structure over the surface; and a conductive trace comprising a first portion within the trench and a second portion above the surface, the conductive trace extending laterally a length, wherein the length is greater than a width of the conductive trace.

Example 2: The apparatus of example 1, wherein the first portion extends a depth below the surface, the second portion extends a height above the surface, and the depth is at least twenty percent of the height.

Example 3: The apparatus of example 1 or example 2, wherein the second portion comprises a sidewall with a concave profile.

Example 4: The apparatus of example 1 or example 2, wherein the second portion comprises a sidewall with a planar profile.

Example 5: The apparatus of any of examples 1 through 3, wherein the conductive trace comprises a third portion over the surface and extending laterally away from the trench.

Example 6: The apparatus of any of examples 1 through 3, or example 5, wherein the routing structure comprises a first side proximate the surface, a second side opposite the first side, and a metallization feature coupling the conductive trace with an interconnect feature at the second side.

Example 7: The apparatus of example 6, wherein the surface is a first surface, the trench is a first trench, the conductive trace is a first conductive trace, the length is a first length, and the width is a first width, the glass panel further comprising: a second surface opposite the first surface, the second surface comprising a second trench; and a second conductive trace extending laterally a second length within the second trench, the second conductive trace comprising a second width, wherein the second conductive trace comprises a third portion within the second trench, a fourth portion above the second surface, and the second length is greater than the second width.

Example 8: The apparatus of example 7, wherein the routing structure is a first routing structure, the metallization feature is a first metallization feature, and the interconnect feature is a first interconnect feature, further comprising: a second routing structure over the second surface, the second routing structure comprising a third side proximate the second surface, a fourth side opposite the third side, and a second metallization feature coupling the second conductive trace with a second interconnect feature at the fourth side.

Example 9: The apparatus of example 8, wherein the glass panel further comprises a through-glass via extending between the first conductive trace and the second conductive trace.

Example 10: The apparatus of example 8, further comprising an integrated circuit (IC) die coupled with the first interconnect feature.

Example 11: An apparatus comprising: a glass panel comprising a first surface, a second surface opposite the first surface, and a trench in the first surface; a conductive trace comprising a first portion within the trench and a second portion above the first surface, the conductive trace extending laterally a length between first and second locations on the first surface, the second location spaced away from the first location; and a through glass via (TGV) extending between the first and second surfaces, wherein the TGV is coupled with the conductive trace at the first location.

Example 12: The apparatus of example 11, further comprising: a first routing structure over the first surface, the first routing structure comprising a first side proximate the first surface, a second side opposite the first side, and a first metallization feature coupling the conductive trace at the second location with a first interconnect feature at the second side; and a second routing structure over the second surface, the second routing structure comprising a third side proximate the second surface, a fourth side opposite the third side, and a second metallization feature coupling the TGV with a second interconnect feature at the fourth side.

Example 13: The apparatus of example 12, further comprising an integrated circuit (IC) die coupled with the first interconnect feature and a host component coupled with second interconnect feature.

Example 14: The apparatus of example 12, further comprising a power supply coupled with the second interconnect feature.

Example 15: The apparatus of example 11 or example 12, wherein the first portion extends a depth below the first surface, the second portion extends a height above the first surface, and the depth is at least ten percent of the height.

Example 16: The apparatus of example 11, example 12, or example 15, wherein the conductive trace comprises a third surface away from the first surface, a sidewall, and a corner where the third surface and the sidewall meet, the sidewall comprising a profile with an overhang at the corner.

Example 17: The apparatus of example 11 or example 12, wherein the first portion comprises a first width at the first surface; the second portion comprises a second width at the first surface; and the second width is greater than or less than the first width.

Example 18: A method comprising: forming a trench on a first surface of a glass panel; forming a conductive trace, the forming of the conductive trace comprising depositing a conductive material on the first surface and on second surfaces within the trench; and forming a first routing structure over the first surface.

Example 19: The method of claim 18, wherein the forming of the conductive trace further comprises: applying a mask comprising a photoresist material over the conductive material; and etching portions of the conductive material within openings in the mask.

Example 20: The method of claim 18, wherein the forming of the conductive trace further comprises: applying a seed layer on the first surface and the second surfaces; applying a mask comprising a photoresist material over the seed layer; and wherein the depositing the conductive material further comprises electroplating the conductive material at locations defined by openings in the mask.

What is claimed is:

1. An apparatus comprising:
a glass panel comprising a surface, a trench in the surface, and a routing structure over the surface; and
a conductive trace comprising a first portion within the trench and a second portion above the surface, the conductive trace extending laterally a length, wherein the length is greater than a width of the conductive trace.

2. The apparatus of claim 1, wherein the first portion extends a depth below the surface, the second portion extends a height above the surface, and the depth is at least twenty percent of the height.

3. The apparatus of claim 1, wherein the second portion comprises a sidewall with a concave profile.

4. The apparatus of claim 1, wherein the second portion comprises a sidewall with a planar profile.

5. The apparatus of claim 1, wherein the conductive trace comprises a third portion over the surface and extending laterally away from the trench.

6. The apparatus of claim 1, wherein the routing structure comprises a first side proximate the surface, a second side opposite the first side, and a metallization feature coupling the conductive trace with an interconnect feature at the second side.

7. The apparatus of claim 6, wherein the surface is a first surface, the trench is a first trench, the conductive trace is a first conductive trace, the length is a first length, and the width is a first width, the glass panel further comprising:
a second surface opposite the first surface, the second surface comprising a second trench; and
a second conductive trace extending laterally a second length within the second trench, the second conductive trace comprising a second width, wherein the second conductive trace comprises a third portion within the second trench, a fourth portion above the second surface, and the second length is greater than the second width.

8. The apparatus of claim 7, wherein the routing structure is a first routing structure, the metallization feature is a first metallization feature, and the interconnect feature is a first interconnect feature, further comprising:
a second routing structure over the second surface, the second routing structure comprising a third side proximate the second surface, a fourth side opposite the third side, and a second metallization feature coupling the second conductive trace with a second interconnect feature at the fourth side.

9. The apparatus of claim 8, wherein the glass panel further comprises a through-glass via extending between the first conductive trace and the second conductive trace.

10. The apparatus of claim 8, further comprising an integrated circuit (IC) die coupled with the first interconnect feature.

11. An apparatus comprising:
a glass panel comprising a first surface, a second surface opposite the first surface, and a trench in the first surface;
a conductive trace comprising a first portion within the trench and a second portion above the first surface, the conductive trace extending laterally a length between first and second locations on the first surface, the second location spaced away from the first location; and
a through glass via (TGV) extending between the first and second surfaces, wherein the TGV is coupled with the conductive trace at the first location.

12. The apparatus of claim 11, further comprising:
a first routing structure over the first surface, the first routing structure comprising a first side proximate the first surface, a second side opposite the first side, and a first metallization feature coupling the conductive trace at the second location with a first interconnect feature at the second side; and
a second routing structure over the second surface, the second routing structure comprising a third side proximate the second surface, a fourth side opposite the third side, and a second metallization feature coupling the TGV with a second interconnect feature at the fourth side.

13. The apparatus of claim 12, further comprising an integrated circuit (IC) die coupled with the first interconnect feature and a host component coupled with second interconnect feature.

14. The apparatus of claim 12, further comprising a power supply coupled with the second interconnect feature.

15. The apparatus of claim 11, wherein the first portion extends a depth below the first surface, the second portion extends a height above the first surface, and the depth is at least ten percent of the height.

16. The apparatus of claim 11, wherein the conductive trace comprises a third surface away from the first surface, a sidewall, and a corner where the third surface and the sidewall meet, the sidewall comprising a profile with an overhang at the corner.

17. The apparatus of claim 11, wherein the first portion comprises a first width at the first surface;
the second portion comprises a second width at the first surface; and
the second width is greater than or less than the first width.

18. A method comprising:
forming a trench on a first surface of a glass panel;
forming a conductive trace, the forming of the conductive trace comprising depositing a conductive material on the first surface and on second surfaces within the trench; and
forming a first routing structure over the first surface.

19. The method of claim 18, wherein the forming of the conductive trace further comprises:
applying a mask comprising a photoresist material over the conductive material; and
etching portions of the conductive material within openings in the mask.

20. The method of claim 18, wherein the forming of the conductive trace further comprises:
applying a seed layer on the first surface and the second surfaces;
applying a mask comprising a photoresist material over the seed layer; and
wherein the depositing the conductive material further comprises electroplating the conductive material at locations defined by openings in the mask.
